(19) United States
(12) Patent Application Publication
(10) Pub. No.: US 2025/0323184 A1
(43) Pub. Date: Oct. 16, 2025

(54) Molded Electronic Component Having a Shunt Between a Load Terminal and a Sense Terminal

(71) Applicant: Infineon Technologies AG, Neubiberg (DE)

(72) Inventors: Thorsten Scharf, Lappersdorf (DE); Dirk Ahlers, München (DE)

(21) Appl. No.: 18/634,386

(22) Filed: Apr. 12, 2024

(51) Int. Cl. H01L 23/62; H01L 23/00; H01L 23/31

(52) U.S. Cl. CPC H01L 23/62; H01L 23/3107; H01L 24/40; H01L 24/48; H01L 2224/40175; H01L 2224/48245

(57) ABSTRACT

A molded electronic component includes a power semiconductor die, a load terminal, a sense terminal separate from the load terminal, and a shunt. The power semiconductor die is at least partly embedded in a mold compound. The load terminal and the sense terminal are each partly embedded in the mold compound. A first side of the shunt is attached to the load terminal. The molded electronic component includes a first connection between a first contact pad of the power semiconductor die and a second side of the shunt opposite the first side, and a second connection between the sense terminal and the second side of the shunt. The shunt has a higher specific resistance than the first connection. A resistance of the shunt varies by less than 10 percent over a normal operating temperature range of the molded electronic component.

### BACKGROUND

Demand for electronic components for power applications continues to increase rapidly across a wide range of industries, including automotive, consumer electronics, renewable energy, manufacturing, and medical, among many others. Developments in semiconductor materials such as silicon carbide (SIC), silicon (Si), and gallium nitride (GaN) have enabled power electronic components with advantageous features such as smaller footprint, higher voltage and current capabilities, and faster switching speeds.

Many applications for power electronic components require accurate and fast current measurements during their operation. Power distribution applications, e.g., for autonomous vehicles, may require accurate current sensing for safety features for applications such as power steering and electromechanical braking. These safety features may include detection of failures such as short circuits, devices that disconnect an affected circuit area, and parallel devices that dissipate current. Motor drives such as brushless motor inverters may also require current sensing capabilities.

Current sense functions in such applications are normally implemented on the circuit board by separate components. These typically include either shunt resistors or magnetic sensors (Hall or GMR/TMR), which are expensive and consume space on the board. Some power electronic components include an integrated current sensor such as a magnetic sensor, but these typically require at least two additional pins for connection and may thus exceed the spatial constraints for some applications. Finally, current measurement cells may be integrated into a chip, however with such a solution there is typically a balance between control and accuracy, size, and cost.

Thus, there is a need for a cost-effective solution that enables accurate measurement of current in a power electronic component with low spatial requirement.

### SUMMARY

According to an embodiment of a molded electronic component, the molded electronic component comprises: a power semiconductor die at least partly embedded in a mold compound; a load terminal partly embedded in the mold compound; a sense terminal separate from the load terminal and partly embedded in the mold compound; a shunt having a first side attached to the load terminal; a first connection between a first contact pad of the power semiconductor die and a second side of the shunt opposite the first side; and a second connection between the sense terminal and the second side of the shunt, wherein the shunt has a higher specific resistance than the first connection, and wherein a resistance of the shunt varies by less than 10 percent over a normal operating temperature range of the molded electronic component.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a perspective view of a molded electronic component, according to an embodiment.

FIGS. 2A and 2B illustrate perspective views of a shunt of a molded electronic component, according to embodiments.

FIG. 3 illustrates a perspective view of a molded electronic component, according to an embodiment.

FIG. 4 illustrates a perspective view of a molded electronic component, according to an embodiment.

FIGS. 5A-5C illustrate perspective views of a molded electronic component, according to embodiments.

### DETAILED DESCRIPTION

Described herein is a molded electronic component having an integrated current sensor that is enabled by including a shunt between a load terminal and a sense terminal of the molded electronic component. Specifically, a first side of the shunt is attached to the load terminal, and a first connection (e.g., a clip, one or more bond wires or metallic ribbons) connects a contact pad of a power semiconductor die included in the molded electronic component to a second, opposite side of the shunt. The shunt has a higher specific resistance (also referred to as electrical resistivity) than the first connection, in some examples at least 10 times higher than a specific resistance of the first connection, and thus a majority of the voltage drop between the contact pad of the power semiconductor die and the load terminal occurs across the shunt. Additionally, the resistance of the shunt has a low variation with temperature (e.g., less than 10 or even less than 5 percent over a normal operating temperature range of the molded electronic component). A potential at the second side of the shunt to which the first connection is attached may thus be similar (e.g., less than 10 percent or even less than 5 percent variation) to the potential at the contact pad of the power semiconductor die within the operating range of the molded electronic component, and measuring the potential at the second side of the shunt may provide a relatively accurate measurement of the current at the contact pad.

To enable such a measurement, the sense terminal of the molded electronic component is connected to the second side of the shunt with a second connection (e.g., a clip, one or more bond wires or metallic ribbons). The potential of the second side of the shunt may be measured at the sense terminal and may thus provide a relatively accurate current measurement. Integrating a current sensor into the molded electronic component in this manner may be simpler, cheaper, and/or require less space (e.g., by requiring only a single extra terminal) than other solutions for integrating a current sensor into a molded electronic component or an electric circuitry.

Described next, with reference to the figures, are exemplary embodiments of a molded electronic component having a shunt that enables a more accurate, space-efficient, and/or cost-effective implementation of an integrated current sensor.

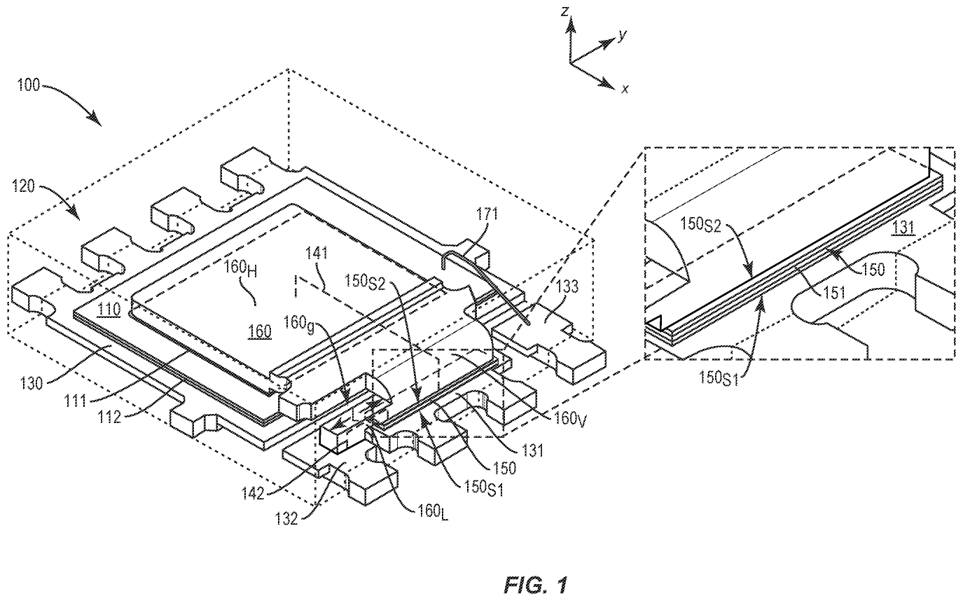

FIG. 1 illustrates a perspective view of a molded electronic component 100, according to an embodiment. The molded electronic component 100 is shown as a surface-mount device (SMD) but instead may be a through-hole device or another type of molded electronic component. The molded electronic component 100 includes a power semiconductor die 110. The power semiconductor die 110 includes one or more devices, e.g., one or more transistors, diodes, resistors, capacitors, and/or other types of active or passive devices. In some examples, the power semiconductor die 110 may be a power transistor die such as a power MOSFET (metal-oxide-semiconductor field-effect transistor) die. In other examples, the power semiconductor die 110 may be a HEMT (high-electron mobility transistor) die, IGBT (insulated-gate bipolar transistor) die, JFET (junction field-effect transistor) die, etc. The semiconductor material of the power semiconductor die 110 may be SiC, GaN, Si, etc. While a single power semiconductor die 110 is shown in the example of FIG. 1, the molded electronic component 100 may include two or more power semiconductor dies 110.

In the example of FIG. 1, the power semiconductor die 110 is a vertical power semiconductor die (e.g., a vertical power transistor die) having a first contact pad 111 and a second contact pad 112 on opposite sides of the power semiconductor die 110. The second contact pad 112 of this example is attached to a lead frame 130 (e.g., a copper or aluminum lead frame). For a vertical power transistor die, the primary current flow path is between the front and back sides of the power semiconductor die 110 (along the z direction in FIG. 1). This is only one example, however, and other types of devices and arrangements of the power semiconductor die 110 are contemplated (e.g., a lateral or planar power MOSFET).

The molded electronic component 100 includes a load terminal 131 and a sense terminal 132. The load terminal 131 and the sense terminal 132 are physically separate from one another. The load terminal 131 and the sense terminal 132 may each be formed from a sheet, plate, or other body of a metal or metal alloy, e.g., copper, aluminum, etc. The load terminal 131 and the sense terminal 132 may, for example, be segments that have been separated from the lead frame 130 during manufacturing of the molded electronic component 100. Alternatively, the lead frame 130, the load terminal 131, and/or the sense terminal 132 may be segments of a substrate such as a printed circuit board (PCB), a DCB (direct copper bonded) or AMB (active metal brazed) substrate, an insulated metal substrate (IMS), etc. A third terminal 133 that is separate from the load terminal 131 and the sense terminal 132 is also illustrated in FIG. 1 although is not a requirement of the molded electronic component 100. The third terminal 133 may, for example, be a control terminal (e.g., a gate terminal) of a MOSFET of the power semiconductor die 110. In this example, the third terminal 133 is electrically connected to the power semiconductor die 110 by an elongated electrically conductive body 171 (e.g., a bond wire or metallic ribbon). The molded electronic component 100 may include one or more additional terminals (not shown).

Each of the power semiconductor die 110, the load terminal 131, the sense terminal 132, and, in this example, the lead frame 130 and the third terminal 133 is at least partly embedded in a mold compound 120. A mold compound is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound may be formed by injection molding, compression molding, film-assisted molding (FAM), reaction injection molding (RIM), resin transfer molding (RTM), blow molding, etc.

In the example of the molded electronic component 100, the load terminal 131 provides electrical access to the first contact pad 111 of the power semiconductor die 110. The first contact pad 111 and the load terminal 131 are electrically connected through a first connection 141 and a shunt 150. Specifically, a first side 150_{S1} of the shunt 150 is attached to the load terminal 131. The first side 150_{S1} of the shunt 150 may, for example, by soldered, diffusion soldered, sintered, glued, or welded to the load terminal 131. The first connection 141 is between the first contact pad 111 of the power semiconductor die 110 and a second side 150_{S2} of the shunt 150 opposite the first side 150_{S1}. The first connection 141 may, in some examples, be soldered, diffusion soldered, sintered, glued, or welded to the second side 150_{S2} of the shunt 150. A second connection 142 of the molded electronic component 100 is between the sense terminal 132 and the second side 150_{S2} of the shunt 150.

The first connection 141 and the second connection 142 of the molded electronic component 100 are implemented by a single metallic body 160 in FIG. 1. The metallic body 160 may, for example, be a metallic clip (e.g., copper, aluminum) as illustrated in FIG. 1. The first connection 141 includes a horizontal segment 160_{H} of the metallic body 160 that is disposed above the power semiconductor die 110 and attached to the first contact pad 111 of the power semiconductor die 110. In this example, a vertical bridging segment 160_{V} of the metallic body 160 connects the horizontal segment 160_{H} to the second side 150_{S2} of the shunt 150. The vertical bridging segment 160_{V} may, for example, be soldered, diffusion soldered, sintered, glued, or welded to the second side 150_{S2} of the shunt 150. Examples in which the horizontal segment 160_{H} extends and connects directly to the second side 150_{S2} of the shunt 150 are contemplated. In some examples, the horizontal segment 160_{H} may include a slight bend in lieu of the vertical bridging segment 160_{V} to compensate for a height difference between the first contact pad 111 and the shunt 150. The second connection 142 includes a lateral bridging segment 160_{L} of the metallic body 160 that connects the sense terminal 132 to the second side 150_{S2} of the shunt 150.

The shunt 150 includes a layer or layer stack 151 of a shunt material, e.g., a foil such as a rolled foil, a tape. In some examples, the shunt material is an alloy including copper and nickel. The shunt material may, for example, be a copper-nickel alloy or a copper-nickel-manganese alloy. The layer or layer stack 151 of the shunt material may have a thickness from about 20 micrometers up to 250 micrometers or more (e.g., from 20 to 100 micrometers for a low voltage molded electronic component 100). In some examples, the layer or layer stack 151 of the shunt material has a thickness of up to 700 micrometers (e.g., for a high voltage molded electronic component 100). The load terminal 131 and/or the first connection 141 may be directly attached to the layer or layer stack 151 of the shunt material, or may be attached to another part of the shunt 150 (e.g., a current spreader, a solder stop, a corrosion protector).

According to an embodiment, the shunt 150 has a higher specific resistance than the first connection 141. For example, the specific resistance of the shunt 150 may be at least 8 times higher than the specific resistance of the first connection 141. In some examples, the specific resistance of the shunt 150 is at least 10 times higher than the specific resistance of the first connection 141. A resistance of the shunt 150 varies by less than 10 percent over a normal operating temperature range of the molded electronic component 100. In some examples, a resistance of the shunt 150 varies by less than 5 percent over a normal operating temperature range of the molded electronic component 100, e.g., down to 2 percent. A normal operating temperature range of the molded electronic component 100 may, for example, be from about −40° C. to about 175° C. (e.g., for automotive applications) or from about −25° C. to about 150° C. (e.g., for industrial applications). In some examples, up to 10 percent of the total product resistance of the molded electronic component 100 may be attributed to the shunt 150.

To ensure the total module resistance does not exceed a target maximum value, the first connection 141 is made of a material having a relatively low specific resistance such as copper or aluminum. However, metals or metal alloys that predominantly comprise copper or aluminum have a specific resistance that strongly depends on temperature. In the absence of the shunt 150, a voltage drop between the first contact pad 111 of the power semiconductor die 110 and the load terminal 131 is distributed entirely across the first connection 141 (in this example, the metallic body 160). Additionally, the voltage drop is strongly temperature dependent without the shunt 150 included in the path, degrading current sense accuracy.

By including the shunt 150, which has a comparatively high specific resistance relative to the first connection 141 and low specific resistance variability (e.g., less than 10 percent, less than 5 percent, or even down to 2 percent over the component temperature operating range), in the electrical pathway between the first contact pad 111 of the power semiconductor die 110 and the load terminal 131, the majority of the voltage drop between the first contact pad 111 and the load terminal 131 occurs across the shunt 150. Thus, with the shunt 150 provided and arranged as illustrated, the voltage drop across the shunt 150 is relatively temperature independent (e.g., less than 10 percent, less than 5 percent, or even down to 2 percent variation over the component temperature operating range), which ensures accurate current sensing.

Connecting the sense terminal 132 to the second side 150_{S2} of the shunt 150 with the second connection 142 enables a measurement of the potential at the second side 150_{S2} of the shunt 150 to be taken at the sense terminal 132 with negligible current flow through the second connection 142, conceivably providing a relatively temperature independent measurement at the sense terminal 132 of the potential and current at the first contact pad 111 of the power semiconductor die 110. The low variation of the specific resistance of the shunt 150 with temperature may ensure that the portion of the voltage drop between the first contact pad 111 of the power semiconductor die 110 and the load terminal 131 that occurs across the shunt 150 remains relatively constant across the normal operating temperature range of the molded electronic component 100, potentially increasing the accuracy of current measurements taken at the sense terminal 132. Integrating a current sense function into the molded electronic component 100 in this manner may be more accurate, cheaper to implement, and/or may require less space than other solutions for measuring the current in a power semiconductor die during operation of a conventional power electronic component.

In FIG. 1, the metallic body 160 included in the molded electronic component 100 has a gap 160_{g} that separates the lateral bridging segment 160_{L} of the metallic body 160 from the horizontal segment 160_{H} of the metallic body 160 over at least part of a length L of the lateral bridging segment 160_{L}. The gap 160_{g} may force a more directional current through the first connection 141 (e.g., in the x and z directions of FIG. 1), thus reducing lateral current flow (e.g., in the y direction of FIG. 1) near the sense terminal 132. Reducing the lateral current flow near the sense terminal 132 by including the gap 160_{g} in the metallic body 160 reduces the voltage drop at the sense terminal 132, which enables a more accurate current sense measurement. Examples in which the gap 160_{g} extends into the horizontal segment 160_{H} and/or the vertical bridging segment 160_{V} are contemplated, including examples in which the gap 160_{g} only extends into the horizontal segment 160_{H} or only extends into the vertical bridging segment 160_{V}.

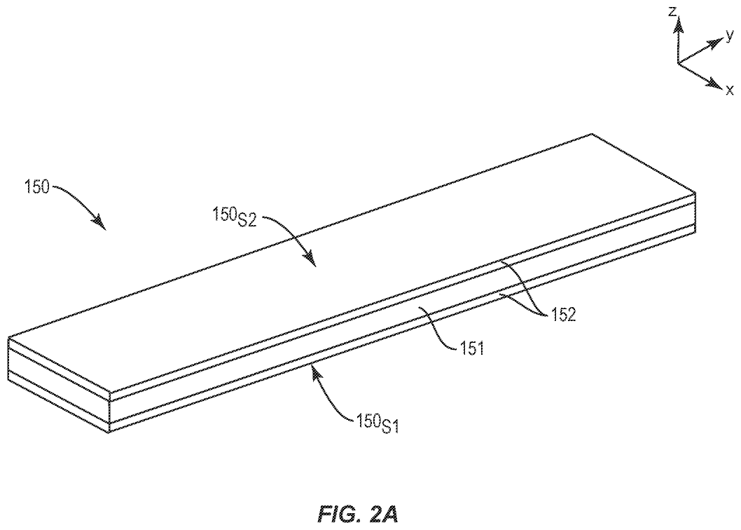

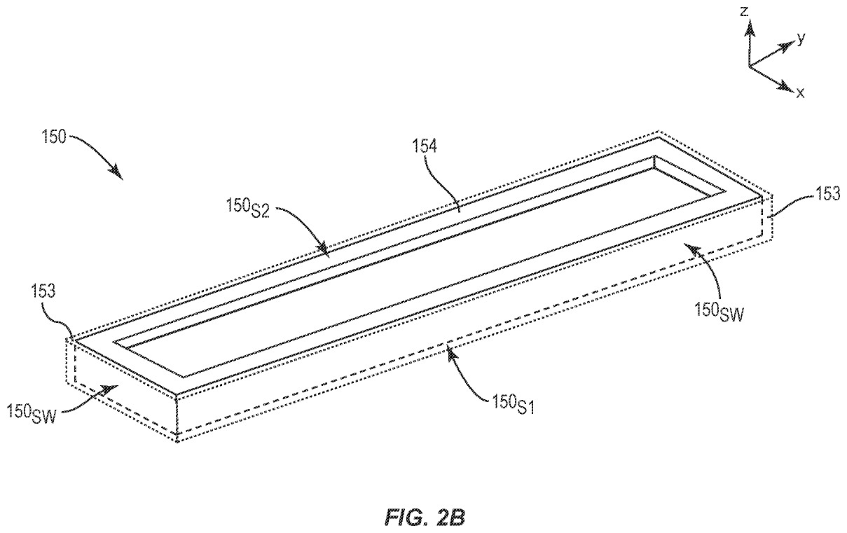

FIGS. 2A and 2B illustrate perspective views of the shunt 150 included in the molded electronic component 100, according to embodiments.

In the example of FIG. 2A, the first side 150_{S1} and the second side 150_{S2} of the shunt 150 each include an end layer or layer stack 152 adjacent to the layer or layer stack 151 of the shunt material. Each end layer or layer stack 152 includes a conductive material different from the shunt material. Example materials of each end layer or layer stack 152 include Cu, Ag, Ni, Sn, and various alloys, among others. Each end layer or layer stack 152 may be a current spreader, a corrosion protector, and/or may serve a different function such as solder wetting. Each end layer or layer stack 152 may cover all or only part of the first side 150_{S1} or the second side 150_{S2} of the shunt 150. For example, a respective end layer or layer stack 152 may include a partial covering (e.g., by plating) of a material (e.g., Ag) on the shunt 150 to define solder areas. In some examples, the respective end layer or layer stack 152 may further or alternatively include a partial covering of a solder stop or resist on the shunt 150 to define non-solder areas.

While the example of FIG. 2A illustrates an end layer or layer stack 152 on both the first side 150_{S1} and the second side 150_{S2} of the shunt 150, examples in which only the first side 150_{S1} or the second side 150_{S2} include an end layer or layer stack 152 are contemplated. In some examples, the end layer or layer stack 152 on the first side 150_{S1} and the end layer or layer stack 152 on the second side 150_{S2} include the same material, have the same function, have the same or similar properties (e.g., thickness), etc. In some examples, the end layer or layer stack 152 on the first side 150_{S1} and the end layer or layer stack 152 on the second side 150_{S2} include different materials, have different functions, have different properties (e.g., thickness), etc.

The shunt 150 in the example of FIG. 2B includes an electrically insulating material 153 on sidewalls 150_{SW} of the shunt 150. The electrically insulating material 153 may be an oxide or nitride, a polymeric coating, or another electrically insulating material. While this example illustrates the electrically insulating material 153 on all sidewalls 150_{SW} of the shunt 150, examples in which the electrically insulating material 153 covers one or some of the sidewalls 150_{SW} are contemplated.

The second side 150_{S2} of the shunt 150 of FIG. 2B includes a solder stop 154 that contains the solder within an area defined by the solder stop 154, for example, a solder used to attach the first connection 141 and/or the second connection 142 to the second side 150_{S2} in the example of FIG. 1. The solder stop 154 of this example covers an outer perimeter of the second side 150_{S2}, although other arrangements are contemplated. In some examples, the solder stop 154 may be combined with the examples of the end layer or layer stack 152 illustrated in FIG. 2A, for example a partial covering of the second side 152_{S2} with an end layer or layer stack 152 to define solderable areas and the solder stop 154 to define non-solderable areas.

While the example of the shunt 150 of FIG. 2B includes both the electrically insulating material 153 on the sidewalls 150_{SW} and the solder stop 154, this is for illustrative purposes only. That is, these are independent and optional features, and some embodiments of the shunt 150 may include only one of the electrically insulating material 153 or the solder stop 154, or neither feature.

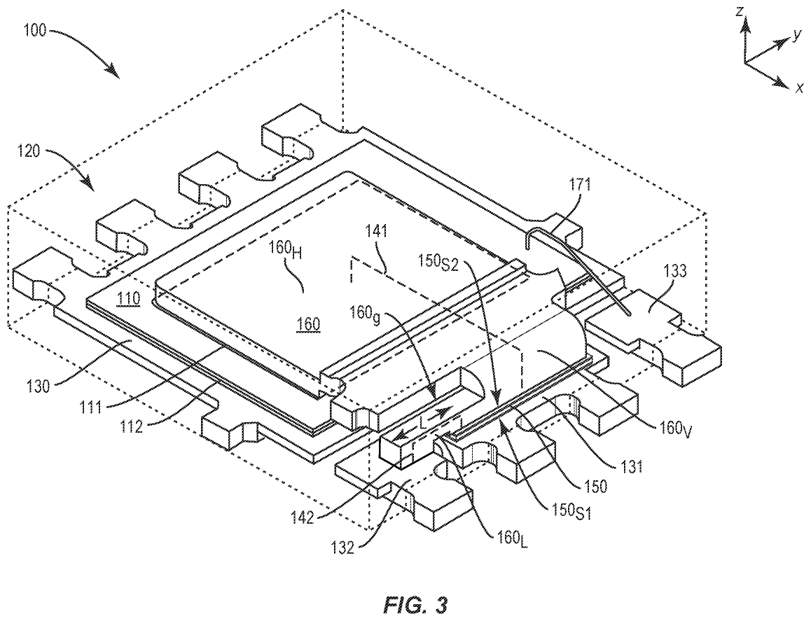

FIG. 3 illustrates a perspective view of the molded electronic component 100, according to an embodiment. Specifically, FIG. 3 illustrates another example of the gap 160_{g} in the metallic body 160 in which the gap 160_{g} is narrower in the x direction and wider in the y direction than the gap 160_{g} in the example of FIG. 1. In this example, the gap 160_{g} extends into the vertical bridging segment 160_{V} beyond the length L of the lateral bridging segment 160_{L}. Other dimensions of the gap 160_{g} are contemplated.

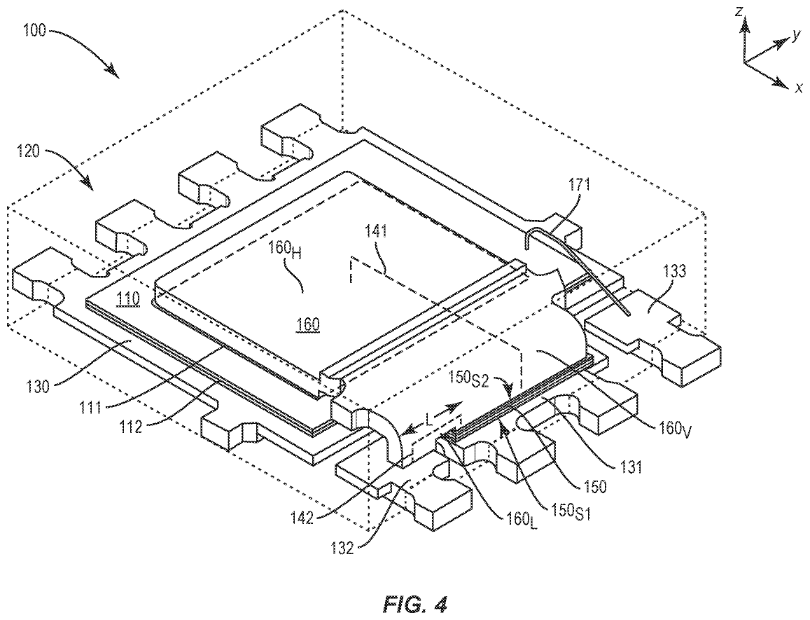

FIG. 4 illustrates a perspective view of the molded electronic component 100, according to an embodiment. Specifically, FIG. 4 illustrates an example that does not include a gap 160_{g} in the metallic body 160. Instead, the lateral bridging segment 160_{L} of the metallic body 160 adjoins the horizontal segment 160_{H} of the metallic body 160 over the length L of the lateral bridging segment 160_{L}.

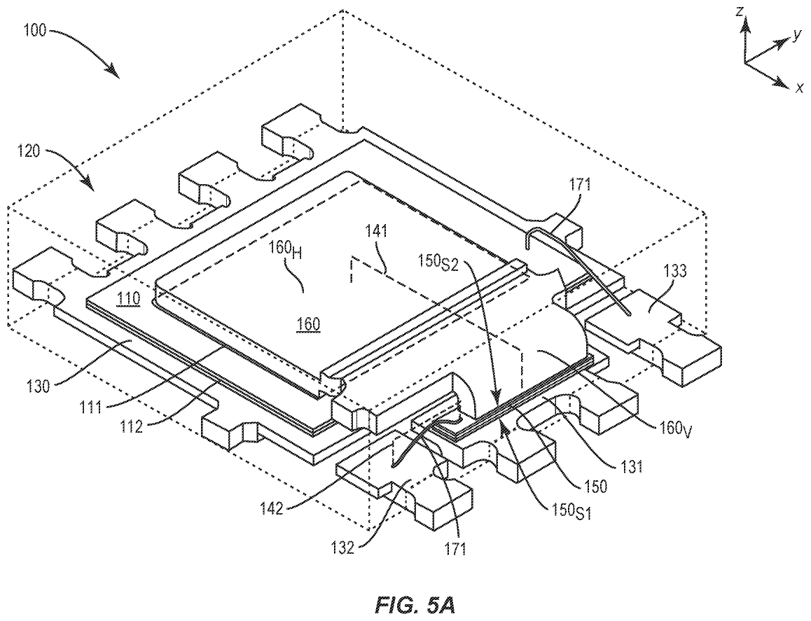

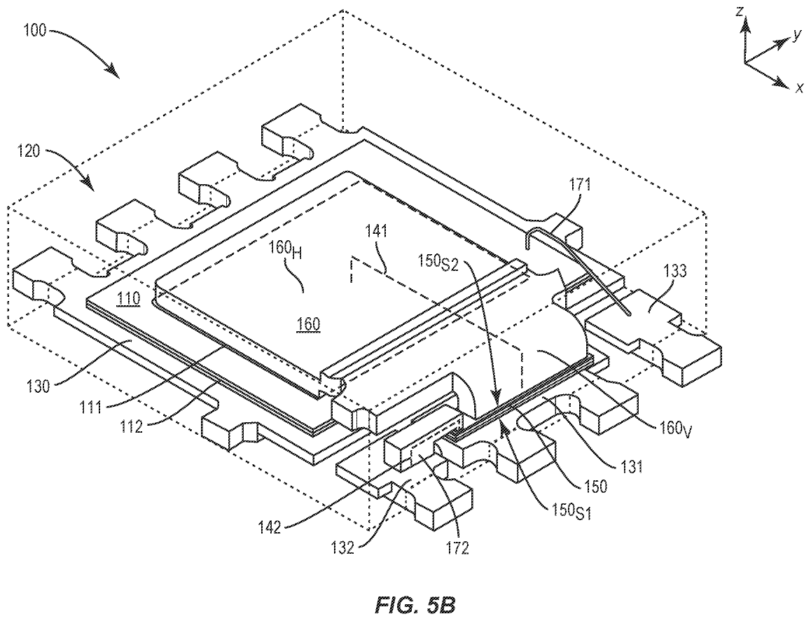

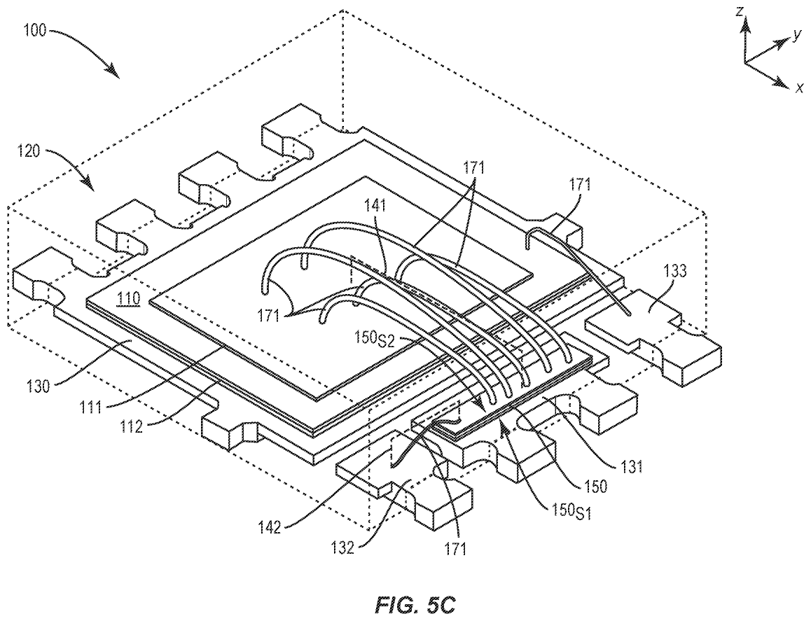

FIGS. 5A-5C illustrate perspective views of the molded electronic component 100, according to embodiments. Specifically, FIGS. 5A-5C illustrate examples of the molded electronic component 100 in which the first connection 141 and the second connection 142 are implemented by physically separate metallic conductors.

In the example illustrated in FIG. 5A, the first connection 141 is implemented by a metallic clip 160. The metallic clip 160 of FIG. 5A may be similar in material composition, structure, etc. to the metallic body 160 of the examples of FIGS. 1, 3, and 4. The metallic clip 160 includes a horizontal segment 160_{H} disposed above the power semiconductor die 110 and attached to the first contact pad 111 of the power semiconductor die 110, and a vertical bridging segment 160_{V} that connects the horizontal segment 160_{H} to the second side 150_{S2} of the shunt 150.

The second connection 142 of FIG. 5A is implemented by one or more elongated electrically conductive bodies 171 that are separate from the metallic clip 160. An elongated electrically conductive body 171 may be a bond wire, metallic ribbon, etc.

FIG. 5B illustrates an example in which the second connection 142 is implemented by a single metallic body 172 (e.g., a metallic clip, as illustrated) that is separate from the metallic clip 160.

FIG. 5C illustrates an example in which the first connection 141 is implemented by one or more electrically conductive bodies 171 (e.g., bond wires and/or metallic ribbons). In this example, the second connection 142 is also implemented by one or more electrically conductive bodies 171, although examples in which the first connection 141 is implemented by one or more electrically conductive bodies 171 and the second connection 142 is implemented by another type of connection (e.g., the single metallic body 172 of FIG. 5B) are contemplated.

Although the present disclosure is not so limited, the following numbered examples demonstrate one or more aspects of the disclosure.

Example 1. A molded electronic component, comprising: a power semiconductor die at least partly embedded in a mold compound; a load terminal partly embedded in the mold compound; a sense terminal separate from the load terminal and partly embedded in the mold compound; a shunt having a first side attached to the load terminal; a first connection between a first contact pad of the power semiconductor die and a second side of the shunt opposite the first side; and a second connection between the sense terminal and the second side of the shunt, wherein the shunt has a higher specific resistance than the first connection, wherein a resistance of the shunt varies by less than 10 percent over a normal operating temperature range of the molded electronic component.

Example 2. The molded electronic component of example 1, wherein the shunt comprises a layer of a shunt material.

Example 3. The molded electronic component of example 2, wherein the shunt material is an alloy comprising copper and nickel.

Example 4. The molded electronic component of example 2 or 3, wherein the layer of the shunt material has a thickness of up to 700 micrometers.

Example 5. The molded electronic component of any of examples 2 through 4, wherein the layer of the shunt material is a foil.

Example 6. The molded electronic component of any of examples 2 through 5, wherein at least one of the load terminal or the first connection is directly attached to the layer of the shunt material.

Example 7. The molded electronic component of any of examples 2 through 6, wherein at least one of the first side of the shunt or the second side of the shunt comprises a layer adjacent to the layer of the shunt material and comprising a conductive material different from the shunt material.

Example 8. The molded electronic component of any of examples 1 through 7, wherein the specific resistance of the shunt is at least 8 times higher than the specific resistance of the first connection.

Example 9. The molded electronic component of any of examples 1 through 8, wherein the first side of the shunt is soldered, diffusion soldered, sintered, glued, or welded to the load terminal.

Example 10. The molded electronic component of any of examples 1 through 9, wherein the first connection is soldered, diffusion soldered, sintered, glued, or welded to the second side of the shunt.

Example 11. The molded electronic component of any of examples 1 through 10, wherein the first connection and the second connection are implemented by a single metallic body, wherein the first connection comprises a horizontal segment of the metallic body that is disposed above the power semiconductor die and attached to the first contact pad of the power semiconductor die, and a vertical bridging segment of the metallic body that connects the horizontal segment to the second side of the shunt, and wherein the second connection comprises a lateral bridging segment of the metallic body that connects the sense terminal to the second side of the shunt.

Example 12. The molded electronic component of example 11, wherein a gap in the metallic body separates the lateral bridging segment of the metallic body from the horizontal segment of the metallic body over at least part of a length of the lateral bridging segment.

Example 13. The molded electronic component of example 11, wherein the lateral bridging segment of the metallic body adjoins the horizontal segment of the metallic body over a length of the lateral bridging segment.

Example 14. The molded electrical component of any of examples 1 through 10, wherein the first connection and the second connection are implemented by physically separate metallic conductors.

Example 15. The molded electronic component of example 14, wherein the second connection is implemented by one or more bond wires and/or metallic ribbons, or a single metallic body.

Example 16. The molded electronic component of example 14 or 15, wherein the first connection is implemented by a metallic clip that comprises a horizontal segment disposed above the power semiconductor die and attached to the first contact pad of the power semiconductor die, and a vertical bridging segment that connects the horizontal segment to the second side of the shunt.

Example 17. The molded electronic component of example 14 or 15, wherein the first connection is implemented by one or more bond wires and/or metallic ribbons.

Example 18. The molded electronic component of any of examples 1 through 17, wherein the shunt comprises an electrically insulating material on at least one sidewall of the shunt.

Example 19. The molded electronic component of any of examples 1 through 18, wherein both the first connection and the second connection are soldered to the second side of the shunt, and wherein the second side of the shunt comprises a solder stop that contains the solder.

Example 20. The molded electronic component of any of examples 1 through 19, wherein a second contact pad on an opposite side of the power semiconductor die from the first contact pad is attached to a lead frame that is partly embedded in the mold compound.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A molded electronic component, comprising:
a power semiconductor die at least partly embedded in a mold compound;
a load terminal partly embedded in the mold compound;
a sense terminal separate from the load terminal and partly embedded in the mold compound;
a shunt having a first side attached to the load terminal;
a first connection between a first contact pad of the power semiconductor die and a second side of the shunt opposite the first side; and
a second connection between the sense terminal and the second side of the shunt,
wherein the shunt has a higher specific resistance than the first connection, and
wherein a resistance of the shunt varies by less than 10 percent over a normal operating temperature range of the molded electronic component.

2. The molded electronic component of claim 1, wherein the shunt comprises a layer of a shunt material.

3. The molded electronic component of claim 2, wherein the shunt material is an alloy comprising copper and nickel.

4. The molded electronic component of claim 2, wherein the layer of the shunt material has a thickness of up to 700 micrometers.

5. The molded electronic component of claim 2, wherein the layer of the shunt material is a foil.

6. The molded electronic component of claim 2, wherein at least one of the load terminal or the first connection is directly attached to the layer of the shunt material.

7. The molded electronic component of claim 2, wherein at least one of the first side of the shunt or the second side of the shunt comprises a layer adjacent to the layer of the shunt material and comprising a conductive material different from the shunt material.

8. The molded electronic component of claim 1, wherein the specific resistance of the shunt is at least 8 times higher than the specific resistance of the first connection.

9. The molded electronic component of claim 1, wherein the first side of the shunt is soldered, diffusion soldered, sintered, glued, or welded to the load terminal.

10. The molded electronic component of claim 1, wherein the first connection is soldered, diffusion soldered, sintered, glued, or welded to the second side of the shunt.

11. The molded electronic component of claim 1,
wherein the first connection and the second connection are implemented by a single metallic body,
wherein the first connection comprises a horizontal segment of the metallic body that is disposed above the power semiconductor die and attached to the first contact pad of the power semiconductor die, and a vertical bridging segment of the metallic body that connects the horizontal segment to the second side of the shunt, and
wherein the second connection comprises a lateral bridging segment of the metallic body that connects the sense terminal to the second side of the shunt.

12. The molded electronic component of claim 11,
wherein a gap in the metallic body separates the lateral bridging segment of the metallic body from the horizontal segment of the metallic body over at least part of a length of the lateral bridging segment.

13. The molded electronic component of claim 11, wherein the lateral bridging segment of the metallic body adjoins the horizontal segment of the metallic body over a length of the lateral bridging segment.

14. The molded electrical component of claim 1, wherein the first connection and the second connection are implemented by physically separate metallic conductors.

15. The molded electronic component of claim 14, wherein the second connection is implemented by one or more bond wires and/or metallic ribbons, or a single metallic body.

16. The molded electronic component of claim 14, wherein the first connection is implemented by a metallic clip that comprises a horizontal segment disposed above the power semiconductor die and attached to the first contact pad of the power semiconductor die, and a vertical bridging segment that connects the horizontal segment to the second side of the shunt.

17. The molded electronic component of claim 14, wherein the first connection is implemented by one or more bond wires and/or metallic ribbons.

18. The molded electronic component of claim 1, wherein the shunt comprises an electrically insulating material on at least one sidewall of the shunt.

19. The molded electronic component of claim 1, wherein both the first connection and the second connection are soldered to the second side of the shunt, and wherein the second side of the shunt comprises a solder stop that contains the solder.

20. The molded electronic component of claim 1, wherein a second contact pad on an opposite side of the power semiconductor die from the first contact pad is attached to a lead frame that is partly embedded in the mold compound.
